(19) United States
(12) Patent Application Publication
(10) Pub. No.: US 2012/0223697 A1
(43) Pub. Date: Sep. 6, 2012

(54) SENSOR FOR MEASURING ELECTRICAL CHARACTERISTICS

(76) Inventors: SangWon Lee, Daejeon (KR); Jae Hyun Kim, Daejeon (KR)

(21) Appl. No.: 13/409,684

(22) Filed: Mar. 1, 2012

Related U.S. Application Data
(63) Continuation of application No. PCT/KR2010/005617, filed on Aug. 24, 2010.

(30) Foreign Application Priority Data
Sep. 3, 2009 (KR) 10-2009-0082930

(51) Int. Cl. G01R 19/15

(52) U.S. Cl. 324/76.11

(57) ABSTRACT

Provided is a sensor for measuring electrical characteristics. The sensor includes a printed circuit board defining a round through-hole into which a power transmission line is inserted; a voltage sensor including a ring-shaped electrode and a first terminal portion to measure a voltage formed in the power transmission line, the electrode being fixed against the inner periphery of the through-hole to measure a voltage formed in the power transmission line, and the first terminal portion having one end in contact with one side of the electrode and the other end exposed through one side of the printed circuit board; and a current sensor including a pickup coil and a second terminal portion to measure current flowing in the transmission line.

### CROSS-REFERENCE TO RELATED APPLICATIONS

This application is a continuation of and claims priority to PCT/KR2010/005617 filed Aug. 24, 2010, which claims priority to Korea Patent Application No. 10-2009-0082930 filed on Sep. 24, 2009, the entirety of which is hereby incorporated by reference herein.

### BACKGROUND

1. Field of the Invention

The present invention relates to sensors and, more particularly, to a sensor capable of measuring electrical characteristics such as current and voltage.

2. Description of the Related Art

Alternating current (AC) has been used in various industrial fields as means for power supply and signal transmission. Due to the low probability of transmission line corrosion and the ease of voltage transformation, alternating current has been widely used as a method for transmitting power generated by an electric generator to a load and has been used as signal or power supply means of communication and medical equipments. In addition, alternating current has been widely used as power supply means to generate plasma inside a semiconductor manufacturing equipment such as a plasma etching chamber.

Since operating characteristics of some electronic devices are very sensitive to electrical characteristics of alternating current supplied from a power supply, electrical characteristics of power must be controlled minutely. Moreover, a sensor is required to precisely measure electrical characteristics of the power supplied for the minute control.

In case of, for example, a plasma etching chamber, an impedance matching system is disposed between a power supply and a load consuming power supplied from the power supply to maximize power transfer efficiency. Since the impedance matching is conducted based on a result of measuring the power supplied to the load from the power supply, a sensor for measuring various electrical characteristics is disposed in the vicinity of a transmission line connecting the power and the load to each other.

In general, a sensor includes an inductor (i.e., coil) to measure current flowing along a transmission line. Since alternating current flowing along the transmission line generates an induced electromotive force induced to the inductor, the current on the transmission line may be determined by measuring the induced electromotive force induced to the inductor. A typical inductor includes a conductive line that winds a doughnut-shaped structure. However, an inductor for use in a conventional inductor has been manufactured by a method in which a conductive line winds a doughnut-shaped structure by a person's hand or a machine. When an inductor is manufactured by such a winding method, it is difficult to make intervals between winding wires regular. Therefore, it may be difficult for the sensor itself to have high precision required, and qualities of products may be different from each other. As mentioned above, precise measurement is needed for precise control of supplied power (i.e., precise matching of impedance). As a result, there is a demand for a sensor system capable of providing higher precision.

### SUMMARY

Embodiments of the present invention provide a sensor capable of obtaining the uniform quality of respective products and measuring electrical characteristics more accurately.

In an aspect of the present invention, the sensor may include a printed circuit board defining a round through-hole into which a power transmission line is inserted; a voltage sensor including a ring-shaped electrode and a first terminal portion to measure a voltage formed in the power transmission line, the electrode being fixed against the inner periphery of the through-hole to measure a voltage formed in the power transmission line, and the first terminal portion having one end in contact with one side of the electrode and the other end exposed through one side of the printed circuit board; and a current sensor including a pickup coil and a second terminal portion to measure current flowing in the transmission line, the pickup coil being wound like a spring and bent along the outer periphery of the through-hole to form a doughnut shape, when viewed from above, and arranged with at least one portion thereof embedded in the printed circuit board, and the second terminal portion extending from both the ends of the pick up coil and being exposed through one side of the printed circuit board.

In another aspect of the present invention, the sensor may include a printed circuit board defining an insertion groove whose one end is open to allow a power transmission line to be inserted thereinto; a voltage sensor including a electrode having a circular arc shape and a first terminal portion to measure a voltage formed in the power transmission line, the electrode being fixed against a portion of the inner periphery of the insertion hole, and the first terminal portion having one end in contact with one side of the electrode and the other end exposed through one side of the printed circuit board; and a current sensor including a pickup coil and a second terminal portion to measure current flowing in the transmission line, the pickup coil being wound like a spring and bent along an outside portion of the inner periphery of the insertion groove to form a circular arc, when viewed from above, and arranged with at least one portion thereof embedded in the printed circuit board, and the second terminal portion extending from both the ends of the pick up coil and being exposed through one side of the printed circuit board.

According to an exemplary embodiment, the printed circuit board may further include a Faraday shield disposed between the pickup coil and the insertion groove to prevent the voltage formed by the power transmission line from transferring to the pickup coil.

According to an exemplary embodiment, the printed circuit board may further include a shield case disposed and grounded between the Faraday shield and the power transmission line to ground the Faraday shield.

According to an exemplary embodiment, a slit may be further formed the Faraday shield in a direction perpendicular to the direction of current flowing in the power transmission line.

According to an exemplary embodiment, the pickup coil may be disposed such that a longitudinal section of the doughnut shape or the circular arc shape forms a quadrangle.

According to an exemplary embodiment, the pickup coil may be wound while being repeatedly exposed to the upper side of the printed circuit board and embedded in the printed circuit board before being repeatedly exposed to the lower side of the printed circuit board and embedded in the printed circuit board.

### BRIEF DESCRIPTION OF THE DRAWINGS

The present invention will become more apparent in view of the attached drawings and accompanying detailed description. The embodiments depicted therein are provided by way of example, not by way of limitation, wherein like reference numerals refer to the same or similar elements. The drawings are not necessarily to scale, emphasis instead being placed upon illustrating aspects of the present invention.

FIG. 1 is a top plan view of a sensor for measuring electrical characteristics according to one embodiment of the present invention.

FIG. 2 is a perspective view in which a portion of a printed circuit board is removed from the sensor illustrated in FIG. 1.

FIG. 3 is a perspective view in which the printed circuit board is removed from the sensor illustrated in FIG. 1.

FIG. 4 is a top plan view of a sensor for measuring electrical characteristics according to another embodiment of the present invention.

FIG. 5 is an enlarge perspective view in which a portion of a printed circuit board is removed from the sensor illustrated in FIG. 4.

FIG. 6 is an enlarged perspective view showing that the sensor illustrated in FIG. 5 is further provided with a shield case.

### DETAILED DESCRIPTION

Exemplary embodiments of the present invention will now be described more fully hereinafter with reference to the accompanying drawings. Terms or words used in this specification and the attached claims should not be limited to typical or lexical meanings, but should be analyzed as meanings and concepts which correspond with the technical spirit of the present invention, based on a principle in which the inventor can properly define the concepts of the terms to explain the present invention through the best method.

Therefore, the embodiments described in this specification and the constructions illustrated in the drawings are only preferred embodiments of the present invention, and may not describe the technical spirit thoroughly. Accordingly, it should be understood that various equivalents and modifications which can substitute the embodiments may be provided at a point of application time of this specification.

The present invention may, however, be embodied in different forms and should not be constructed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention. The drawings are not necessarily to scale and in some instances, proportions may have been exaggerated in order to clearly illustrate features of the embodiments.

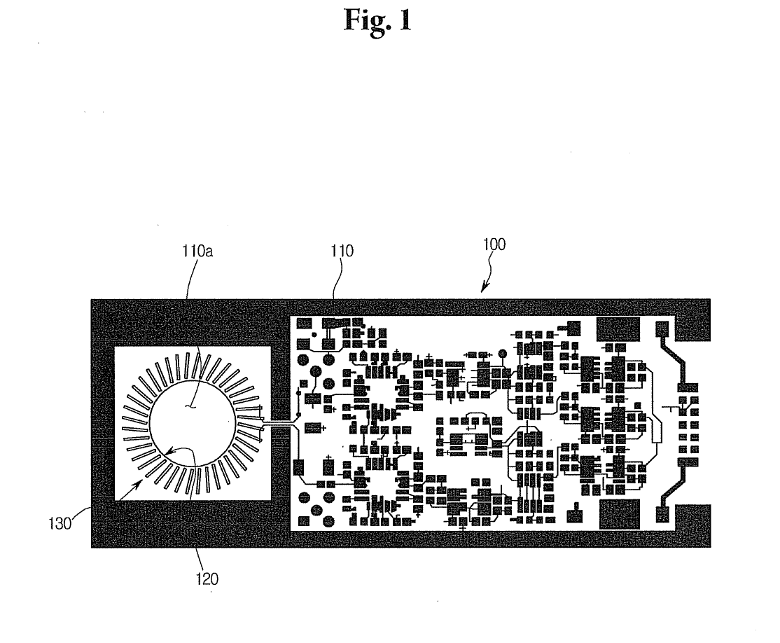

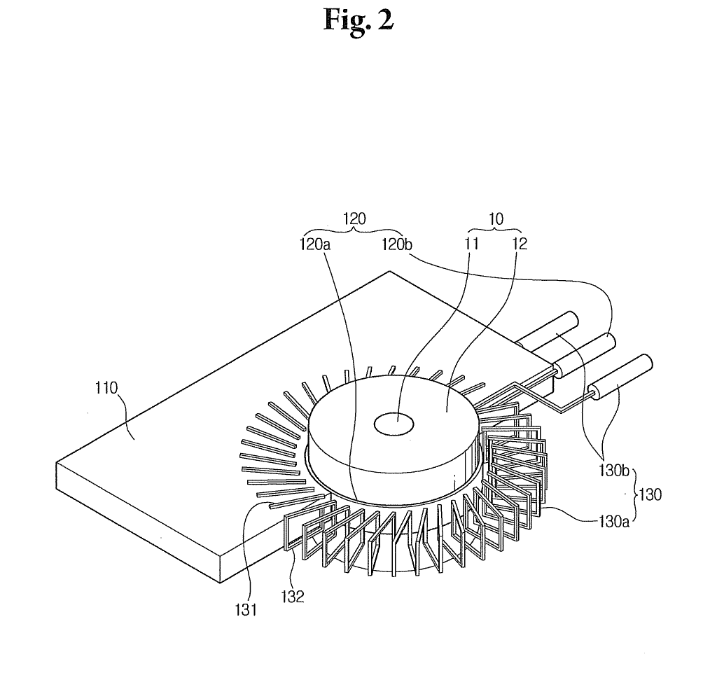

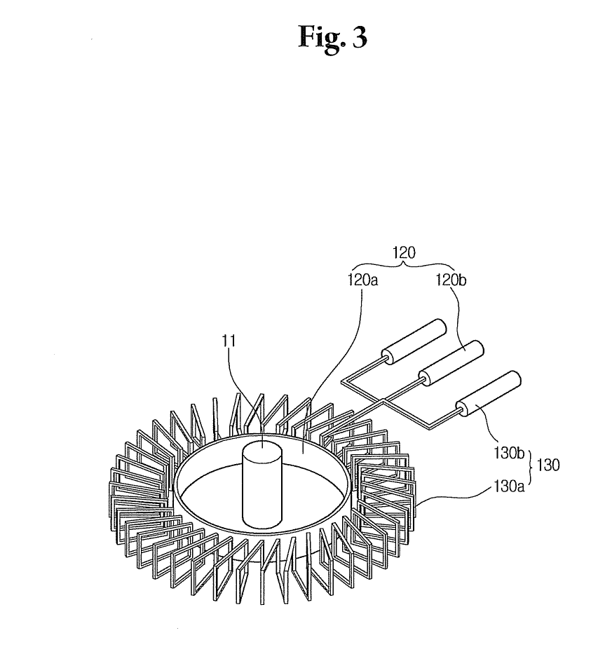

Hereafter, a sensor for measuring electrical characteristics according to one embodiment of the present invention will be described in detail. FIG. 1 is a top plan view of a sensor for measuring electrical characteristics according to one embodiment of the present invention. FIG. 2 is a perspective view in which a portion of a printed circuit board is removed from the sensor illustrated in FIG. 1, and FIG. 3 is a perspective view in which the printed circuit board is removed from the sensor illustrated in FIG. 1.

Referring to FIGS. 1 to 3, a sensor 100 for measuring electrical characteristics includes a printed circuit board (PCB) 110, a voltage sensor 120, and a current sensor 130.

The PCB 110 is a board having one surface or both surfaces on which printed circuits are formed. The PCB 110 defines a round through-hole into which a power transmission line is inserted. In general, the power transmission line 10 comprises a core conductor 11 and a dielectric substance 12. Current having various electrical characteristics may flow along the power transmission line 10. Particularly, radio-frequency (RF) high current may flow along the power transmission line 10.

The voltage sensor 120 is configured to measure a voltage formed in the power transmission line 10 and includes a ring-shaped electrode 120a and a first terminal portion 120b. The electrode 120a of the voltage sensor 120 is fixed against the inner periphery of the through-hole 110a of the PCB 110. One end of the first terminal portion 120b is in contact with one side surface of the electrode 120a, and the other end thereof is exposed through one side of the PCB 110. A commercial capacitor, a resistor, an inductor or the like are connected to the exposed end of the first terminal portion 120b, which may allow a voltage to be detected by the capacitor, the resistor, the inductor or the like. The first terminal portion 120b may be embedded in the PCB 110 or exposed to a top or bottom surface of the PCB 110.

The current sensor 130 includes a pickup coil 130a and a second terminal portion 130b.

As shown in FIGS. 2 and 3, the pickup coil 130a is wound like a spring and bent along the outer periphery of the through-hole 110a to form a doughnut shape. The pickup coil 130a measures a current flowing in the power transmission line 10 by means of an induced current. The pickup coil 130a is disposed with at least one portion thereof embedded in the PCB 110.

More specifically, the pickup coil 130a is disposed such that a doughnut-shaped longitudinal section forms a quadrangle. It is matter of course that not only quadrangle but also various shapes are available. Nonetheless, as will be set forth later, a quadrangular shape is more stable in consideration of the fact that the pickup coil 130a is exposed in contact with the PCB 110.

In this case, the pickup coil 130a is wound while being repeatedly exposed to the upper side of the PCB 110 and embedded in the PCB 110 before being repeatedly exposed to the lower side of the PCB 110 and embedded in the PCB 110. That is, a vertically bent portion of the pickup coil 130a is embedded in the PCB 110 while an upper horizontally bent portion 131 is exposed in contact with the upper side of the PCB 110 and a lower horizontally bent portion 132 is exposed in contact with the lower side of the PCB 110. The second terminal portion 130b extends from both the ends of the pickup coil 130a and is exposed through a side of the PCB 110 to measure the current flowing in the power transmission line 10.

Next, a sensor for measuring electrical characteristics according to another embodiment of the present invention will now be described below in detail.

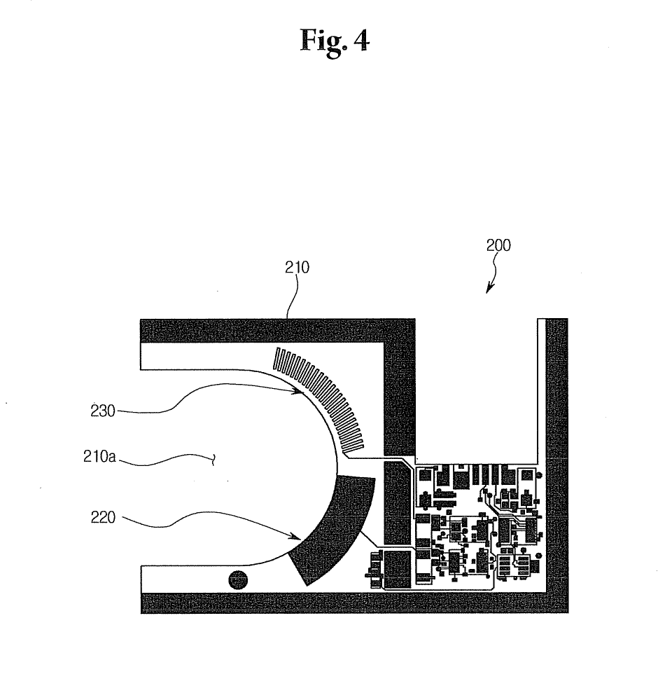

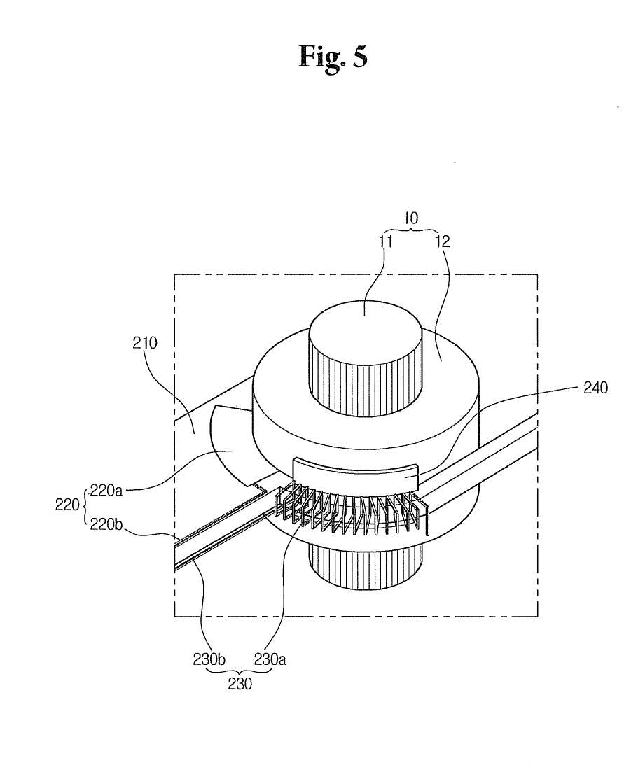

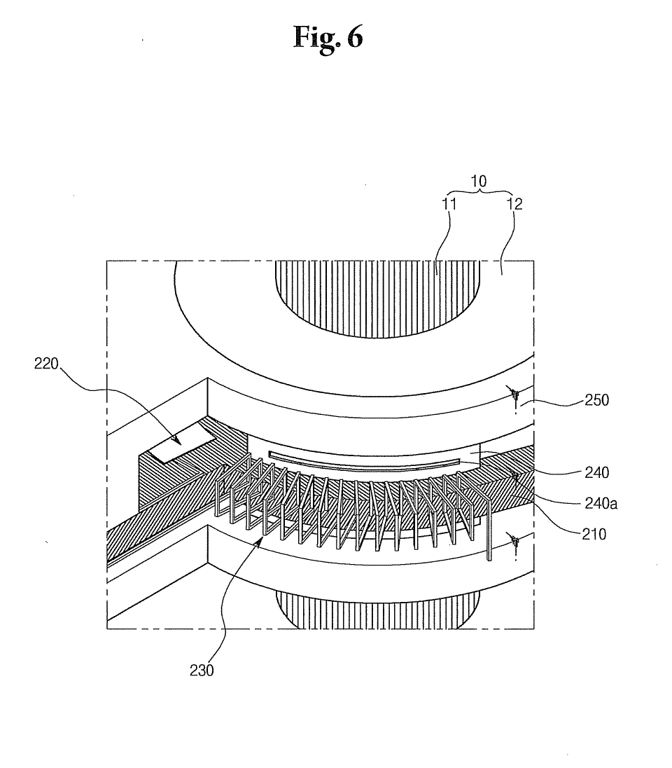

FIG. 4 is a top plan view of a sensor for measuring electrical characteristics according to another embodiment of the present invention. FIG. 5 is an enlarge perspective view in which a portion of a printed circuit board is removed from the sensor illustrated in FIG. 4, and FIG. 6 is an enlarged perspective view showing that the sensor illustrated in FIG. 5 is further provided with a shield case.

Referring to FIGS. 4 to 6, a sensor 200 for measuring electrical characteristics includes a printed circuit board (PCB) 210, a voltage sensor 220, and a current sensor 230.

The PCB 210 defines an insertion groove 210a whose one end is open to allow a power transmission line 10 to be inserted thereinto. One end of the insertion groove 210a is open to allow the power transmission line 10 to be inserted thereinto, and the other end thereof has a round shape to correspond to the outer periphery of the power transmission line 10.

The voltage sensor 220 includes an electrode 220a having a circular arc shape and a first terminal portion 220b. The electrode 220a is fixed against a portion of the inner periphery of the insertion groove 210a to measure a voltage formed in the power transmission line 10. One end of the first terminal portion 220b is in contact with one side of the electrode 220a, and the other end thereof is exposed through one side of the PCB 210. The first terminal portion 220b may also be embedded in the PCB 210 or exposed to a top or bottom surface of the PCB 210.

The current sensor 230 includes a pickup coil 230a and a second terminal portion 230b. The pickup coil 230a is wound like a spring and bent along an outer portion of the inner periphery of the insertion groove 210a to form a circular arc, when viewed from above. The pickup coil 230a measures a current flowing in the power transmission line 10 by means of an induced current. The pickup coil 230a is disposed with at least one portion thereof embedded in the PCB 210.

More specifically, similar to the above-described pickup coil 130a of the sensor 100, the pickup coil 230a is disposed such that a longitudinal section having a circular arc shape forms a quadrangle. It is matter of course that not only quadrangle but also various shapes are available. Nonetheless, as will be set forth later, a quadrangular shape is more stable in consideration of the fact that the pickup coil 230a is exposed in contact with the PCB 210.

In this case, the pickup coil 230a is wound while being repeatedly exposed to the upper side of the PCB 210 and embedded in the PCB 210 before being repeatedly exposed to the lower side of the PCB 210 and embedded in the PCB 210. That is, a vertically bent portion of the pickup coil 230a is embedded in the PCB 210 while an upper horizontally bent portion is exposed in contact with the upper side of the PCB 210 and a lower horizontally bent portion is exposed in contact with the lower side of the PCB 210. The second terminal portion 230b extends from both the ends of the pickup coil 230a and is exposed through a side of the PCB 210 to measure the current flowing in the power transmission line 10.

The PCB 210 further includes a Faraday shield 240 disposed between the pickup coil 230a and the insertion groove 210a to prevent a voltage formed by the power transmission line 10 from transferring to the pickup coil 230a. In addition, the PCB 210 further includes a shield case 250 disposed and grounded between the Faraday shield 240 and the power transmission line 10 to ground the Faraday shield 240. At least one slit 240a may be formed at the Faraday shield 240 in a direction perpendicular to the direction of the current flowing in the power transmission line 10. If the slit 240a is fowled at the Faraday shield 240, an electric field established by the power transmission line 10 is prevented from transferring to the pickup coil 230a while a magnetic field is allowed to transfer to the pickup coil 230a. Thus, the current of the pickup coil 230a may be measured more accurately.

According to the embodiment of the present invention described above, the electrode 120a or 220a and the pickup coil 130a or 230a are integrally formed on the printed circuit board (PCB) 110 or 210. Thus, the uniform quality may be obtained and the electrical characteristics of the power transmission line 10 may be measured very accurately. In addition, since the voltage sensor 120 or 220 and the current sensor 130 or 230 are arranged around the power transmission line 10, a complete non-contact type structure is provided where there is no part that is in direct contact with the core conductor 11 in the power transmission line 10. Moreover, since there are adoptable both the sensor 100 having the through-hole 110a fanned to fully cover the power transmission line 10 and the sensor 200 having the insertion groove 210a formed to partially cover the power transmission line 10, the PCB 110 or 210 may selectively use the sensors 100 and 200, if necessary.

In the case that the Faraday shield 240 is used, a voltage formed in the power transmission line 10 may be prevented from transferring to the pickup coil 130a or 230a to measure a more precise value. Additionally, in the case that the shield case 250 is used together with the Faraday shield 240, the Faraday shield 240 may be grounded to measure a more precise value.

According to the embodiments of the present invention described above, a sensor for measuring electrical characteristics has the advantages, as set forth below.

First, since an electrode and a pickup coil are integrally formed on a printed circuit board (PCB), electrical characteristics of a power transmission line can be measured very accurately.

Second, since a current sensor and a voltage sensor are arranged around a power transmission line, a complete non-contact type structure can be provided where there is no part that is in direct contact with a core conductor in the power transmission line.

Third, since there are adoptable both a structure having a through-hole formed to fully cover a power transmission line and a structure having an insertion hole formed to partially cover the power transmission line, the sensors can be selectively used, if necessary.

Fourth, in the case that a Faraday shield is used, a voltage foamed in a power transmission line can be prevented from transferring to a pickup coil to measure a more precise value.

Fifth, in the case that a shield case is used together with a Faraday shield is used, the Faraday shield can be grounded to measure a more precise value.

According to the present invention described above, since an electrode and a pickup coil are integrally formed on a printed circuit board (PCB), the uniform quality can be obtained and electrical characteristics of a power transmission line can be measured very accurately. Moreover, since a current sensor and a voltage sensor are arranged around the power transmission line, a complete non-contact type structure can be provided where there is no part that is in direct contact with a core conductor in the power transmission line.

Although the present invention has been described in connection with the embodiment of the present invention illustrated in the accompanying drawings, it is not limited thereto. It will be apparent to those skilled in the art that various substitutions, modifications and changes may be made without departing from the scope and spirit of the present invention.

What is claimed is:

1. A sensor for measuring electrical characteristics, comprising:
a printed circuit board defining a round through-hole into which a power transmission line is inserted;
a voltage sensor including a ring-shaped electrode and a first terminal portion to measure a voltage formed in the power transmission line, the electrode being fixed against the inner periphery of the through-hole to measure a voltage formed in the power transmission line, and the first terminal portion having one end in contact with one side of the electrode and the other end exposed through one side of the printed circuit board; and
a current sensor including a pickup coil and a second terminal portion to measure current flowing in the transmission line, the pickup coil being wound like a spring and bent along the outer periphery of the through-hole to form a doughnut shape, when viewed from above, and arranged with at least one portion thereof embedded in the printed circuit board, and the second terminal portion extending from both the ends of the pick up coil and being exposed through one side of the printed circuit board.

2. A sensor for measuring electrical characteristics, comprising:
a printed circuit board defining an insertion groove whose one end is open to allow a power transmission line to be inserted thereinto;
a voltage sensor including a electrode having a circular arc shape and a first terminal portion to measure a voltage formed in the power transmission line, the electrode being fixed against a portion of the inner periphery of the insertion hole, and the first terminal portion having one end in contact with one side of the electrode and the other end exposed through one side of the printed circuit board; and
a current sensor including a pickup coil and a second terminal portion to measure current flowing in the transmission line, the pickup coil being wound like a spring and bent along an outside portion of the inner periphery of the insertion groove to form a circular arc, when viewed from above, and arranged with at least one portion thereof embedded in the printed circuit board, and the second terminal portion extending from both the ends of the pick up coil and being exposed through one side of the printed circuit board.

3. The sensor as set forth in claim 1, wherein the printed circuit board further includes a Faraday shield disposed between the pickup coil and the insertion groove to prevent the voltage formed by the power transmission line from transferring to the pickup coil.

4. The sensor as set forth in claim 3, wherein the printed circuit board further includes a shield case disposed and grounded between the Faraday shield and the power transmission line to ground the Faraday shield.

5. The sensor as set forth in claim 3, wherein a slit is further formed the Faraday shield in a direction perpendicular to the direction of current flowing in the power transmission line.

6. The sensor as set forth in claim 1, wherein the pickup coil is disposed such that a longitudinal section of the doughnut shape or the circular arc shape forms a quadrangle.

7. The sensor as set forth in claim 6, wherein the pickup coil is wound while being repeatedly exposed to the upper side of the printed circuit board and embedded in the printed circuit board before being repeatedly exposed to the lower side of the printed circuit board and embedded in the printed circuit board.
